(19) United States
(12) Patent Application Publication
(10) Pub. No.: US 2013/0038336 A1
(43) Pub. Date: Feb. 14, 2013

(54) Probe Calibration Device and Calibration Method

(71) Applicants: Jie-Wei SUN, Hsinchu City (TW); Chao-Hsien Wu, Hsinchu City (TW); Chia-Chun Sun, Taipei City (TW); Yun-San Huang, New Taipei City (TW); Chien-Li Kuo, Hsinchu City (TW)

(72) Inventors: Jie-Wei SUN, Hsinchu City (TW); Chao-Hsien Wu, Hsinchu City (TW); Chia-Chun Sun, Taipei City (TW); Yun-San Huang, New Taipei City (TW); Chien-Li Kuo, Hsinchu City (TW)

(73) Assignee: UNITED MICROELECTRONICS CORPORATION, Hsinchu (TW)

(21) Appl. No.: 13/208,440

(22) Filed: Aug. 12, 2011

(51) Int. Cl. G01R 35/00

(52) U.S. Cl. 324/601

(57) ABSTRACT

A calibration device applied for a test apparatus with at least a first probe and a second probe, the calibration device comprising: a first testing region and a second testing region, the first testing region and the second testing region divides into n×n sensing units respectively, the first testing region for generating n×n average electricity corresponding to a contact degree of the first probe contacted with the calibration device, and the second testing region for generating another n×n average electricity corresponding to a contact degree of the second probe contacted with the calibration device, and the pitch is the distance between the center of the first testing region to the center of the second testing region that is the same as that of the center of the first probe to the center of the second probe.

### FIELD OF THE INVENTION

The present invention relates to a probe correction device, and more particularly to a parallel plate capacitor as the probe calibration device to correct the accurately of the probe.

### BACKGROUND OF THE INVENTION

In generally, after the wafer manufacturing process is finished, the electricity and the functional testing of the testing wafer must be performed to identify the operation of the IC chips on the wafer. The wafer test is performed to inspect each chip on the testing wafer by the probe and test apparatus to identify the functional and performance of the IC circuit on the chips which is fabricated according to the design rule of the semiconductor manufacturing process. The inspection processes of the testing wafer include a probe that is fixed on the test head by the test apparatus. Then, the probe is contacted with the pad on the testing wafer to measure the electricity signal of the pad. Next, the electricity signal is communicated to the test apparatus. Thus, the yield of each chip on the testing wafer can be identified according to the electricity signal by the test apparatus. In general, an indentation is formed on the pad when the probe contacted with the pad, and the indentation area is an index for the probe stress contacting with the pad. The size of the indentation area can be observed by the optical microscope. The usage of the probe can also be determined according to the indentation area on the pad. However, the different user will have the different observation standard by using the optical microscope, so that the usage of the probe cannot be exactly determined, for example, the tip of the probe has been suffered a lot of wear and tear, but the probe is still performed to test to affect the testing accuracy for the testing wafer. If the probe still contacted with the pad, the pads would be cracked when the damage has been occurred underneath the pads on the testing wafer.

### SUMMARY OF THE INVENTION

In accordance with an aspect, the present invention provides a calibration method. The electricity is generated corresponding to the contact degree when the probe that is contacted with the calibration device, the electricity can identify the location of the probe and the height difference between the probe and the under testing wafer.

In accordance with an aspect, the present invention provides a calibration device. The probe is calibrated by the calibration device before the under testing wafer inspection is performed. The driving force for the probe can be identified by the electricity. The electricity is generated corresponding to the contact degree when the probe is contacted with the calibration device.

In accordance with an aspect, the present invention provides a correction device. The probe is calibrated by the calibration device before the under testing wafer inspection is performed. The height difference between the probe and the under testing wafer is whether to be adjusted according to the electricity which is generated corresponding to the contact degree when the probe is contacted with the calibration device.

The present invention provides a calibration device which applied for a test apparatus with a first probe and a second probe. The calibration device includes a first testing region and a second testing region, the first testing region and the second testing region includes n×n sensing units respectively, the first testing region for generating n×n average electricity corresponding to the contact degree when the first probe is contacted with the first testing region and a second testing region for generating another n×n average electricity corresponding to the contact degree when the second probe is contacted with the second testing region, wherein the pitch is the distance between the center of the first testing region to the center of the second testing region that is the same as that of the center of the first probe to the center of the second probe.

In an embodiment, the first testing region and the second testing region is a parallel plate capacitor which is made of a top metal layer, a dielectric layer and a bottom metal layer.

In an embodiment, the dielectric layer is an inter-metal dielectric (IMD) layer or inter-layer dielectric (ILD) layer.

In an embodiment, the numerical n is an integer larger than 1.

In an embodiment, the n×n average electricity is average capacitance.

In an embodiment, the first testing region and the second testing region include a first sub testing region and a second sub testing region respectively, and an interconnect structure is electrically connected the first sub testing region with the second sub testing region.

The present invention provides a calibration device which applied for a test apparatus with a first probe and a second probe. The calibration device includes a first testing region and a second testing region. The first testing region and the second testing region include m×m sensing units respectively. The first testing region for generating m×m electricity corresponding to the contact degree when the first probe is contacted with the first testing region, in which the pitch is the distance between the center of first testing region to the center of the second testing region that is the same as that of the center of the first probe to the center of the second probe.

In an embodiment, the first testing region and the second testing region is a parallel plate capacitor which is made of a top metal layer, a dielectric layer and a bottom metal layer.

In an embodiment, the dielectric layer is an inter-metal dielectric (IMD) layer or inter-layer dielectric (ILD) layer.

In an embodiment, the numerical n is an integer larger than 1.

In an embodiment, the n×n average electricity is average capacitance.

In an embodiment, the first testing region and the second testing region include a first sub testing region and a second sub testing region respectively, and an interconnect structure is electrically connected the first sub testing region with the second sub testing region.

In accordance with another aspect, the present invention provides a calibration method which applied for a test apparatus with at least a first probe and a second probe. The steps of the calibration method as follows. Firstly, a first testing region and a second testing region are provided. The pitch is the distance between the center of the first testing region to the center of the second testing region that is the same as that of the center of the first probe to the center of the second probe. The first probe and the second probe are aligned with the first testing region and the second testing region respectively. The first electricity is obtained corresponding to the contact degree of the first probe is contacted with the first testing region and the second electricity is obtained corresponding to the contact degree of the second probe is contacted with the second testing region. The first probe and the second can be calibrated according to the first electricity and/or the second electricity.

In an embodiment, the first testing region and the second testing region is a parallel plate capacitor which is made of a top metal layer, a dielectric layer and a bottom metal layer.

In an embodiment, the dielectric layer is an inter-metal dielectric (IMD) layer or an inter-layer dielectric (ILD) layer.

In an embodiment, the first testing region and the second region are divided into at least n×n sensing units respectively.

In an embodiment, the numerical n is an integer larger than 1.

In an embodiment, the first electricity and the second electricity is capacitance.

In an embodiment, the first electricity and the second electricity is calculated to obtain average electricity. The average height of the first probe and the second probe can be calculated according to the average electricity.

In an embodiment, when the average height is larger than the tolerance, the first probe and/or the second probe with corresponding average height should be changed.

In an embodiment, when the average height of the first probe and the second probe is in the middle of the tolerance, the first probe and the second probe of the test apparatus are adjusted to an inclined angle, so that the first probe and the second probe with same average height to perform the under test wafer inspection process.

In an embodiment, the driving force of the first probe or the second probe can be obtained by calculating the first electricity or the second electricity.

### BRIEF DESCRIPTION OF THE DRAWINGS

The above objects and advantages of the present invention will become more readily apparent to those ordinarily skilled in the art after reviewing the following detailed description and accompanying drawings, in which:

FIG. 1A schematically illustrates a top view of the calibration device according to an embodiment of the present invention;

FIG. 1B schematically illustrates the structure of the testing region according to an embodiment of the present invention;

FIG. 2 schematically illustrates the height difference between the probe and the calibration device is obtained by the test apparatus with a plurality of probes contacted with the calibration device according to an embodiment of the present invention;

FIG. 3A˜3B schematically illustrates the steps of the calibration method for calibrating the average height of the test apparatus with a plurality of probes according to an embodiment of the present invention;

FIG. 3C schematically illustrates that the testing region is divided into n×n sensing units;

FIG. 3D schematically illustrates a diagram for the capacitance and the height difference between the probe and the calibration device according to an embodiment of the present invention;

FIG. 3E˜3G schematically illustrate the steps for calibrating the average height of the test apparatus with a plurality probes according to another embodiment of the present invention;

FIG. 4A˜4B schematically illustrate the steps for calibrating the driving force of the probe according to an embodiment of the present invention;

FIG. 4C schematically illustrates the testing region that includes m×m sensing unit according to an embodiment of the present invention;

FIG. 4D schematically illustrates a diagram of the footprints which is generated by the probe is contacted the testing region.

FIG. 4E schematically illustrates a diagram for the driving force of the probe and the capacitance when the probe is contacted with the calibration device according to an embodiment of the present invention.

FIG. 4F˜4H schematically illustrate the steps for calibrating the driving force of the probe according to another embodiment of the present invention;

### DETAILED DESCRIPTION OF PREFERRED EMBODIMENTS

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

When the probe is contacted with the pads (not shown) on the testing wafer (not shown), the contact degree between the probe and the pads and the displacement of the probe can be identified by the indentation area on pads. In order to avoid the user creating the wrong judgment, the electricity change is generated corresponding to the contact degree when the probe that is contacted with the plurality of testing regions on the calibration device before the inspection of the testing wafer. Thus the probe can be judged to adjust or replace according to the electricity variation to increase the accuracy of the probe and the yield of the testing wafer.

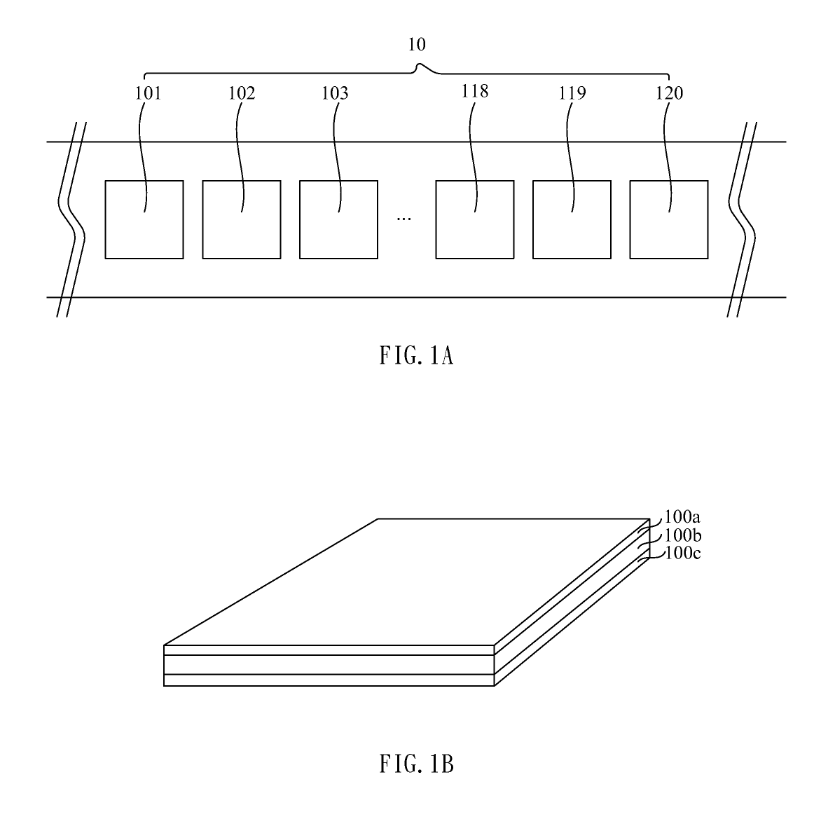

FIG. 1A shows a top view of a calibration device according to the present invention. In FIG. 1A, the calibration device 10 includes a plurality of testing regions 101˜120. The each structure of the testing region 101˜120 is a parallel plate capacitor as shown in FIG. 1B.

Please refer to FIG. 1B, the parallel plate capacitor is formed by a top metal layer 100a, a dielectric layer 100b with a dielectric constant ε and a bottom metal layer 100c. The capacitance for the parallel plate capacitor relates to the geometrical shape of which and the characteristic of the medium in the parallel plate capacitor. When the distance between the top metal layer 100a and the bottom metal layer 100c is small, the electric field located between the top metal layer 100a and the bottom metal layer 100c that regards as a uniform electric field. Thus the capacitance of the parallel plate capacitor expresses C=εA/d, wherein C is capacitance, A is cross-sectional area for the top metal layer 100a and bottom metal layer 100c and d is distance between the top metal layer 100a and the bottom metal layer 100c. When the dielectric constant ε of the dielectric layer 100b is constant, the cross-sectional area for the parallel plate capacitor A is larger than the distance d between the top metal layer 100a and the bottom metal layer 100c. The product εA is a constant which is obtained by the dielectric constant ε products the cross-sectional area A of the dielectric layer. Thus the contacting location for the probe contacting with the parallel plate capacitor and the height between the probe and the parallel plate capacitor can be obtained by the capacitance variation corresponds to the thickness change of the dielectric layer 100b. In addition, the material of the top metal layer 100a and the bottom metal layer 100c is made of metal; the dielectric layer 100b is inter-metal dielectric (IMD) layer or inter-layer dielectric (ILD) layer.

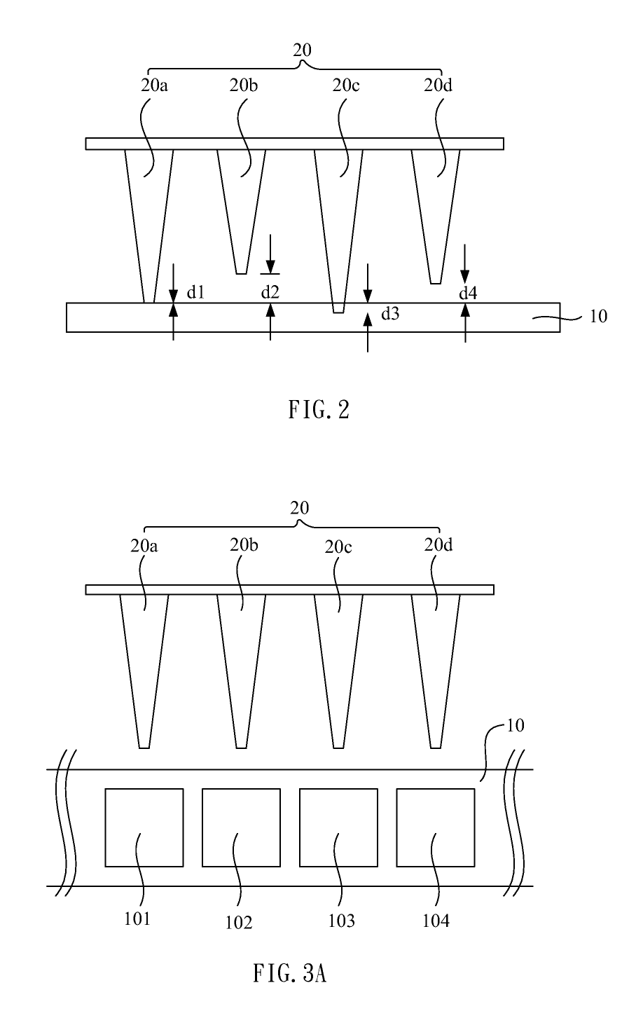

Please refer to FIG. 2, shows the height difference between each probe and the calibration device when the plurality of probes is contacted with the calibration device. Because the usage of each probe is different and the contact degree for each probe contacting with the testing wafer is also different. When each probe 20a˜20d on the testing apparatus 20 is contacted with each testing region (not shown) of the calibration device 10, the situation between each probe 20a˜20d and the calibration device 10 may be occurred as shown in FIG. 2. When the probe 20a is contacted with the testing region (not shown) of the calibration device 10, there is no height difference between the probe 20a and the calibration device 10, the d₁ is zero; the probe 20b is not contact with the calibration device 10, the height difference between the probe 20b and the calibration device 10 is d₂; the probe 20c contacted with the calibration device 10, and the tip of the probe 20c inserted into the calibration device 10, the height difference between the probe 20c and the calibration device 10 is d₃; and the probe 20d is also not contact with the calibration device 10, the height difference between the probe 20d and the calibration device 10 is d₄, and the height difference d₃ is larger than the height difference d₄.

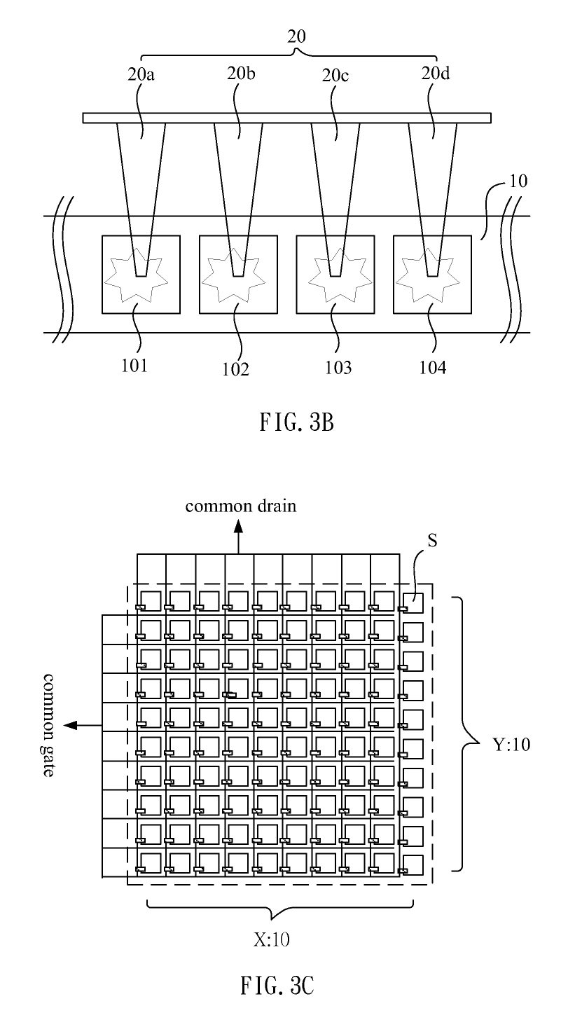

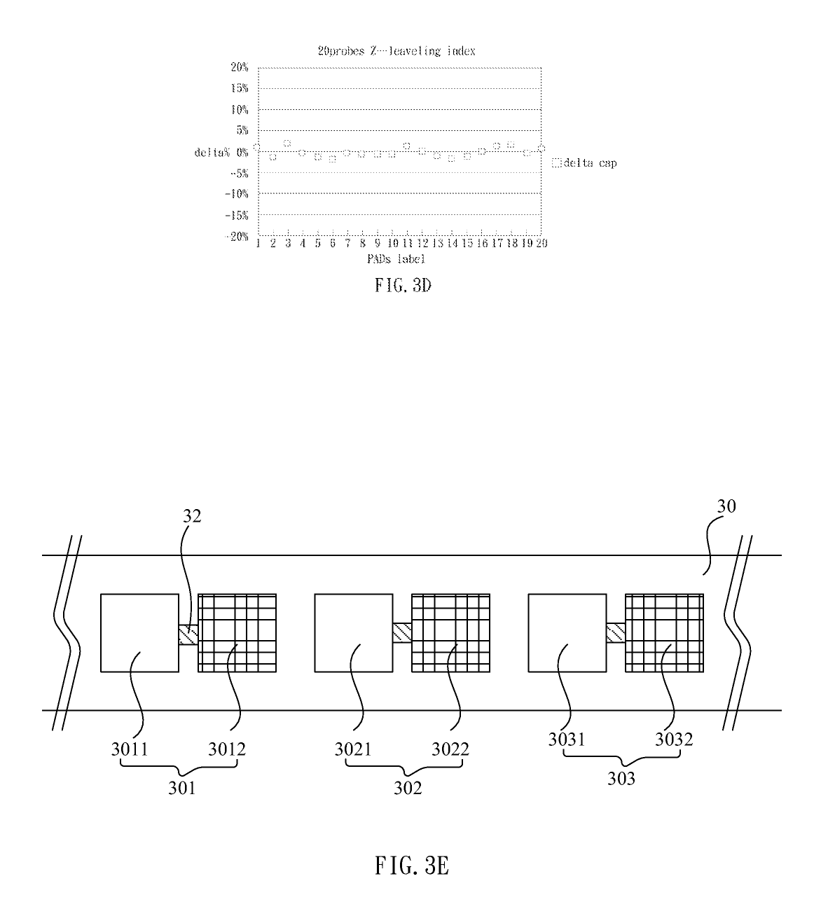

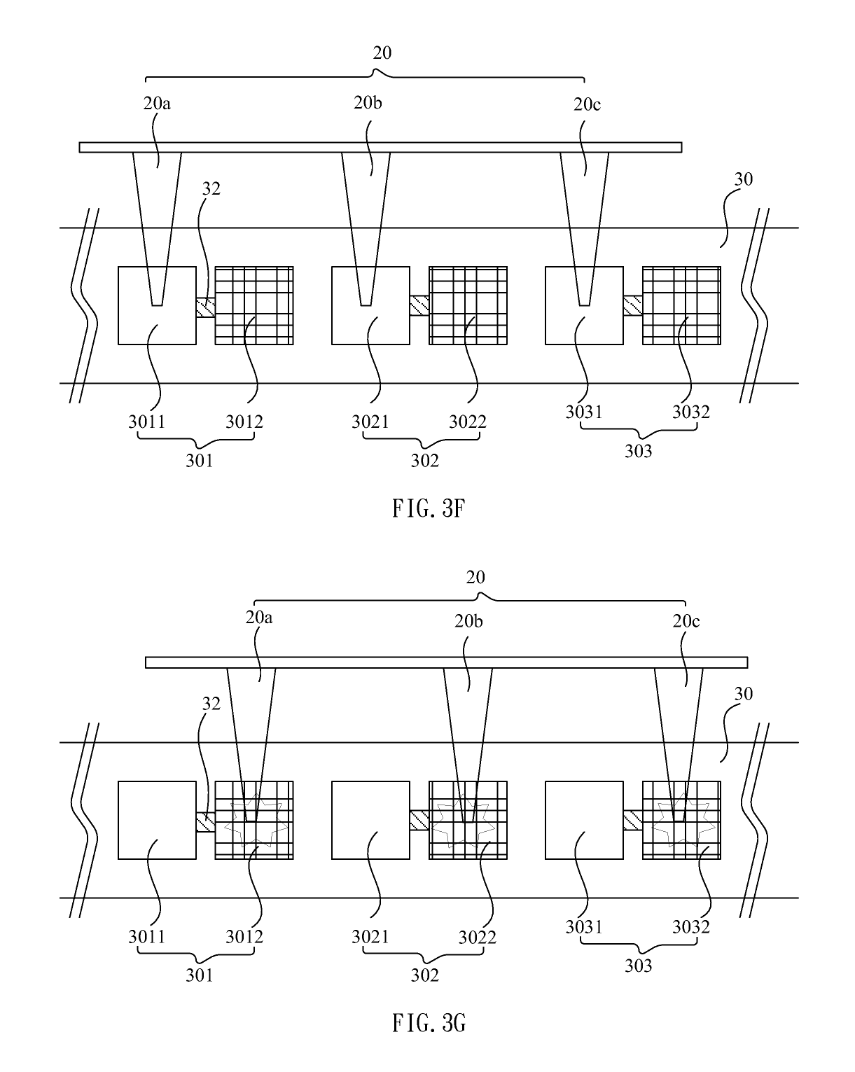

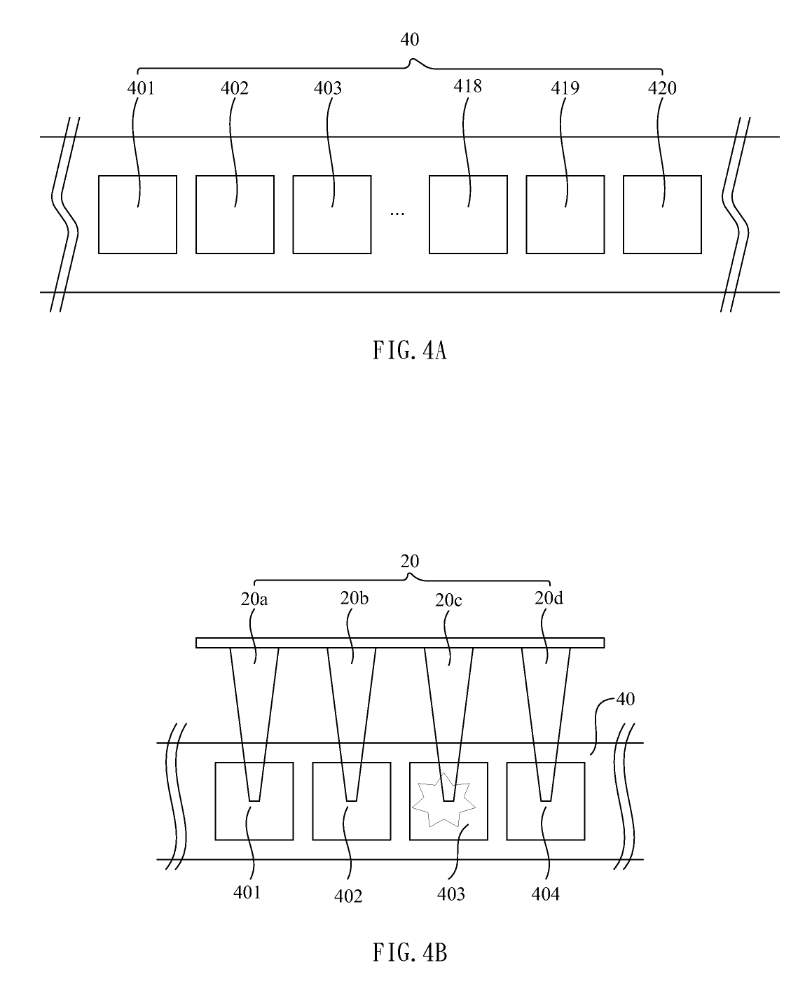

In order to avoid the probe is not contacting or over contacting with the pads of the under testing wafer. The present invention provides a calibration method for the probe to calibrate the height difference between the each probe and the calibration device. FIG. 3A to FIG. 3B show the steps for calibrating the probe. In FIG. 3A, a calibration device 10 includes a plurality of testing regions, in which the detail structure of the calibration device 10 is similar to that of FIG. 1A and it is not to be described herein.

In this embodiment, the plurality of testing regions for the calibration device 10 is arranged under the test apparatus 20. Each plurality of probes of the testing apparatus 20 is aligned with the each testing region of the calibration device 10 respectively. The pitch is the distance between the centers of the two testing regions that is same as that of the centers of the two probes.

Next, please refer to FIG. 3B, the first probe 20a is contacted with the first testing region 101, the second probe 20b is contacted with the second testing region 102, the third probe 20c is contacted with the third testing region 103 and the forth probe 20d is contacted with the forth testing region 104 respectively. The first electricity is obtained corresponding to the contact degree of the first probe 20a contacted with the first testing region 101. The second electricity is obtained corresponding to the contact degree of the second probe 20b contacted with the second testing region 102. The third electricity is obtained corresponding to the contact degree of the third probe contacted with third testing region 103. The forth electricity is obtained corresponding to the contact degree of the forth probe 20d contacted with the forth testing region 104. Then the first electricity, the second electricity, the third electricity and the forth electricity are transferred to the test apparatus 20 through the first probe 20a, the second probe 20b, the third probe 20c and the forth probe 20d respectively. It is to be noted that the terms of the first electricity, the second electricity, the third electricity and the forth electricity is capacitance in the embodiment of this present invention.

In this embodiment, each testing region 101˜104 can be divided into n×n sensing units S1, and the numerical n is an integer larger than 1. For example, n is 10, as shown in FIG. 3C. Therefore, each testing region 101˜104 can be divided into 100 sensing units S1 respectively. The electrical connection for each sensing unit S1 is accomplished by using a common gate and a common drain. When the probes 20a˜20d are contacted with the testing regions 101˜104, the n×n sensing units S1 generated the capacitance corresponding to the driving force of each probe 20a˜-20d contacted with each testing region 101˜104 can be read out. Thus the output capacitance is obtained from the each testing region is the summation of the capacitance of 100 sensing units S1.

Each capacitance is obtained from each testing regions 101˜104 and is substituted into the formula C=εA/d to obtain the thickness variation d of the dielectric layer 100b when the first probe 20a is contacted with the first testing region 101, the second probe 20b is contacted with the second testing region 102, the third probe 20c is contacted with the third testing region 103 and the forth probe 20d is contacted with the forth testing region 104. The optimal testing results can be obtained by the probe contacting the testing region with an appropriate driving force. Thus the capacitance is obtained by the probe contacting the testing region with the appropriate driving force which can be used as a reference value. Thus, a capacitance difference can be estimated by the capacitances which are obtained from the testing regions 101˜104 subtract the reference value. When the capacitance difference is large, the thickness variation d of the dielectric layer of the testing region becomes smaller. It can be obtained that the height difference between the probe and the calibration device 10 is large, for example, the second probe 20b and the forth probe 20d as shown in FIG. 2. In contrast, when the capacitance variation is smaller, the thickness variation d of the dielectric layer of the testing region become larger, that the height variation between the probe and the calibration device 10 is smaller, for example, the first probe 20a and the third probe 20c as shown in FIG. 2.

According to above steps of the calibration method, the diagram between the capacitance and the height difference between the probe and the calibration device can be drawn according to the capacitance variation which is obtained by the each probe contacted with the calibration device. In FIG. 3D, a tolerance can be defaulted in a range ±5%. If the average height of these probes is in the middle of the tolerance, the probes can be adjusted to an inclined angle, such that the height difference between each probe and the calibration device 10 is identical, such that the contact degree of each probe contacted with the under testing wafer is the same when the testing wafer is to be inspected. In addition, if the capacitance of partial probes on the calibration device 10 is larger or smaller the tolerance, the partial probes should to be replaced.

Therefore, the height difference between each probe and the calibration device can be obtained from the capacitance which is generated by the each probe contacted with the calibration device, such that the replacement for the probe or the compensation for the height difference between the probe and the calibration device can be developed.

In another embodiment, the calibration device 30 includes a plurality of testing regions 301˜303, as shown in FIG. 3E. The first testing regions 301 is divided into a first sub testing region 3011 and a second sub testing region 3012, and an interconnect structure 32 is electrically connected the first sub testing region 3011 with the second sub testing region 3012. The second testing region 302 is divided into a first sub testing region 3021 and a second sub testing region 3022, and an interconnect structure 32 is electrically connected the first sub testing region 3021 with the second sub testing region 3022. The third testing region 303 is divided into a first sub testing region 3031 and a second sub testing region 3032, an interconnect structure 32 is electrically connected the first sub testing region 3031 with the second sub testing region 3032 The calibration method for the probe is that the first probe 20a is aligned with the first sub testing region 3011 of the first testing region 301, the second probe 20b is aligned with the first sub testing region 3021 of the second testing region 302, and the third probe 20c is aligned with the first sub testing region 3031 of the third testing region 303 as shown in FIG. 3F.

Next, the first electricity of the first probe 20a is obtained corresponding to the contact degree of the first probe 20a contacted with the first sub testing region 3011 of the first testing region 301, the first electricity of the second probe 20b is obtained corresponding to the contact degree of the second probe 20b contacted with the first sub testing region 3021 of the second testing region 302, and the first electricity of the third probe 20c is obtained corresponding to the contact degree of the third probe 20c contacted with the first sub testing region 3031 of the third testing region 303, where the first electricity of the first probe 20a, the first electricity of the second probe 20b, and the first electricity of the third probe 20c can be used as the reference value for the calibration method. As shown in FIG. 3G, the test apparatus is moved. The first probe 20a is aligned with the second sub testing region 3012 of the first testing region 301, the second probe 20b is aligned with the second sub testing region 3022 of the second testing region 302, and the third probe 20c is aligned with the second sub testing region 3032. Next, the second electricity of the first probe 20a is obtained corresponding to the contact degree of the first probe 20a contacted with the second sub testing region 3012 of the first testing region 301, the second electricity of the second probe 20b is obtained corresponding to the contact degree of the second probe 20b contacted with the second sub testing region 3022 of the second testing region 302, and the second electricity of the third probe 20c is obtained corresponding to the contact degree of the third probe 20c contacted with the second sub testing region 3032 of the third testing region 303. Then the first electricity and the second electricity are calculated for the first probe 20a, the second probe 20b and the third probe 20c to obtain the first average capacitance of the first probe 20a, the second average capacitance of the second probe 20b and the third average capacitance of the third probe 20c respectively.

Next, the first, second, and third average capacitance is substituted into the formula C=εA/d to obtain the thickness variation d of the dielectric layer 100b for the first testing region 301, the second testing region 302 and the third testing region 303. Thus, the capacitance of each testing region 301˜303 can be determined that the average height difference between the each probes 20a˜20c of the test apparatus 20 and the calibration device 30. If the average height difference is in the middle of the tolerance, the test apparatus 20 can be adjusted to an inclined angle, such that each probe of the test apparatus 20 with the same average height difference to contact the under testing wafer (not shown) under the same driving force when the inspection process is performed. In addition, the probe whose capacitance is larger than the tolerance is to be replaced, so that the average height between all probes of the test apparatus 20 and the calibration device is in the middle of the tolerance.

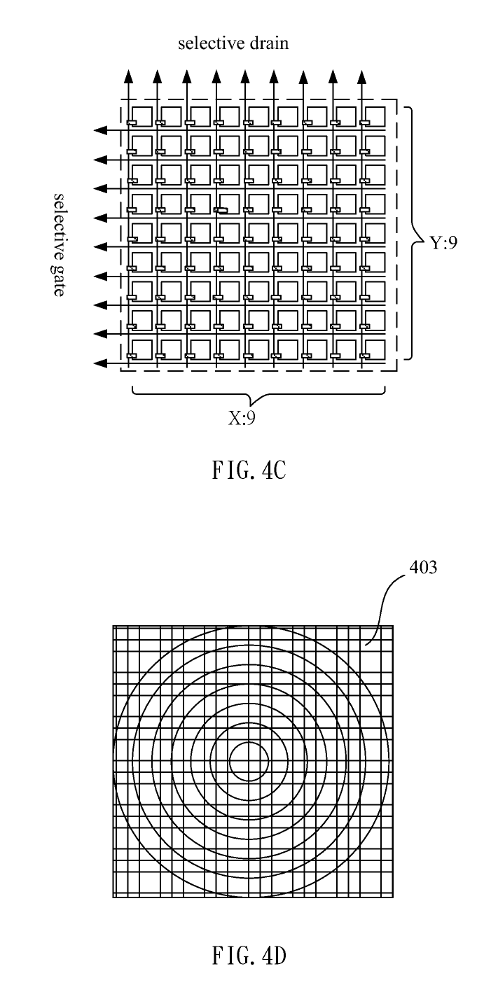

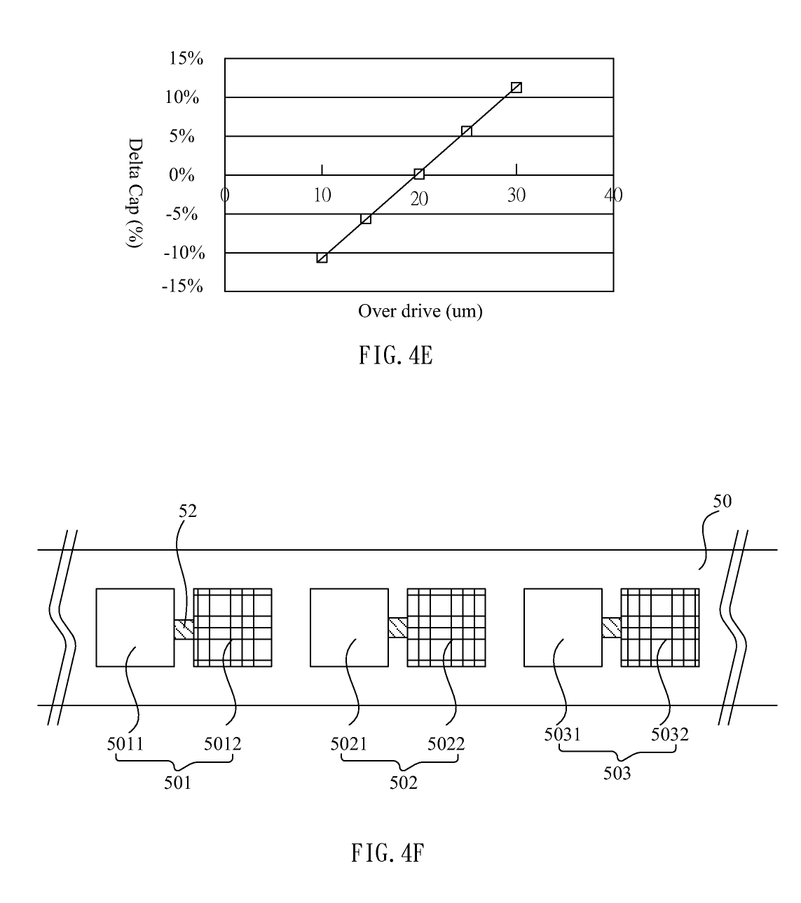

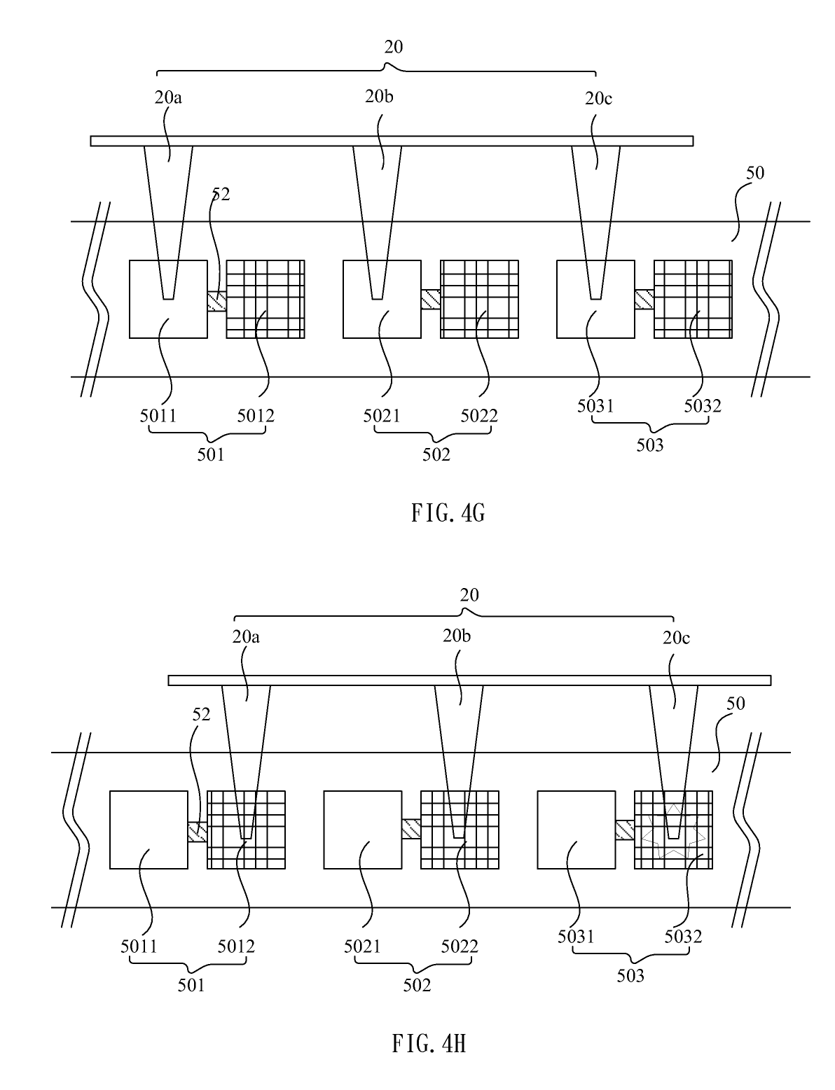

In addition, the present invention also provides another calibration method for calibrating the probe and the calibration device. FIG. 4A. The calibration device 40 includes a plurality of testing region 401˜420 in which the detail structure of the calibration device 10 as similar as the structure of FIG. 1A, thus it is not to be described herein.

Then the plurality of probes 20a˜20d of the test apparatus 20 is arranged over the calibration device 40, each probe 20a˜20d is aligned with each testing region 401˜404, in which the pitch is the distance between the centers of the two testing region that is the same as that of the centers of the two probes.

Then referring to FIG. 4B, the first probe 20a is aligned with the first testing region 401, the second probe 20b is aligned with the second testing region 402, the third probe 20c is aligned with the third testing region 403, and the forth probe 20d is aligned with the forth testing region 404 respectively, but the result for one of them can be selected to represent all of the plurality of probes. As shown in FIG. 4B, the third probe 20c is contacted with the third testing region 403 and the electricity is obtained corresponding to the contact degree of the third probe 20c contacted with the third probe 20c. Then, the electricity of the third probe 20c is transferred to the test apparatus 20.

It is additionally to explain that each testing region 410˜404 can be divided into m×m sensing units S2, in which the numerical m is an integer larger than 1. In FIG. 4C, the numerical n is 9. In FIG. 4C, the electrical connection for each sensing unit S2 is accomplished by using the selective drain and the selective gate respectively. Thus, the 81 capacitances can be obtained from each testing region 401˜404. Thus, in above embodiment, the 81 capacitances can be obtained when the third probe 20c is contacted with the third testing region 403. The optimal testing results can be obtained by the probe contacting the testing region with an appropriate driving force. Thus 81 capacitances can be taken down to be a reference value.

Then, the 81 capacitances are subtracted the reference value to obtain a capacitance difference. The capacitance difference is substituted into the formula C=εA/d to obtain the thickness variation d of the dielectric layer 100b when the third probe 20c is contacted with the third testing region 403, such that the footprints of the third probe 20c can be drawn as shown in FIG. 4D. Thus, the driving force of the probe compared with the tolerance to determine the driving force is increased or not during the inspection process is performed. In addition, the displacement of others probes can be compared with the footprints (FIG. 4D). The leveling of the probe is larger than the tolerance, the probe should be replaced.

In this embodiment, the driving force of the third probe 20c contacted with the third testing region 403 that can be changed to obtain the different capacitance, so that the diagram of the different driving force and the capacitance can be obtained as shown in FIG. 4E. In FIG. 4E, the capacitance can be obtained according to the driving force of the probe contacted with the under testing wafer, and the electricity of the under testing wafer can be determined by the capacitance.

In a further embodiment, as shown in FIG. 4F, the calibration device 50 includes a plurality of testing region 501˜503. The first testing region 501 includes a first sub testing region 5011 and a second sub testing region 5012, and an interconnect structure 52 is electrically connected the first sub testing region 5011 with the second sub testing region 5012. The second testing region 502 includes a first sub testing region 5021 and a second sub testing region 5022, and the interconnect structure 52 is electrically connected the first sub testing region 5021 with the second sub testing region 5022. The third testing region 503 includes a first sub testing region 5031 and a second sub testing region 5032, and the interconnect structure 52 is electrically connected the first sub testing region 5031 with the second sub testing region 5032. The most steps of calibration method are the same as the abovementioned. The difference is that the first probe 20a is aligned with the first sub testing region 5011 of the first testing region 501, the second probe 20b is aligned with the first sub testing region 5021 of the second testing region 502, and the third probe 20c is aligned with the first sub testing region 5031 of the third testing region 503. Next, one of the probes such as third probe 20c is contacted with the first sub testing region 5031 of the third testing region 503 and a first electricity can be obtained according to the contact degree for the third probe 20c contacting with the first sub testing region 5031 of the third testing region 503. Then, as shown in FIG. 4H, the test apparatus 20 is moved to each probe aligns with the second sub testing region of each testing region. Thus, the third probe 20c is aligned with the second sub testing region 5032 of the third testing region 503. When a driving force is applied to the third probe 20c contact with the second sub testing region 5032 of the third testing region 503 to obtain second electricity.

In this embodiment, the first electricity is calculated with the second electricity to obtain a capacitance difference. In other words, the capacitance difference can also be the 81 capacitances which is obtained by 81 capacitances of 81 sensing units of the first sub testing region 5031 is calculated with 81 capacitances of 81 sensing units of the second sub testing region 5032. Similarly, the footprints of the third probe 20c can also be drawn as FIG. 4C. In addition, the diagram between the height difference and the capacitance of FIG. 4D also can be obtained by applying the different driving force to the third probe 20c.

In the present invention, the testing wafer can be WAT pads (wafer acceptance test pads), BOAC pads (bond pad active circuit pads), or CP test pads (circuit probing test pads).

Thus the usage of each probe can be obtained according to above calibration method so as to characterize the probe impact. In addition, the probe height model can be developed for inspection of testing wafer under higher temperature or lower temperature. Moreover, the usage of the probe can be maintained, and the period of use can also be extended. The calibration device 10 also can be applied for dynamic operation of the back-end-of-line of the semiconductor manufacture.

It is to be illustrated that the calibration device and the calibration method can be built in the wafer testing system. The testing system executes the calibration function for calibration the probe before the testing wafer is performed to inspect. The testing system can be controlled by the multiplex (MUX) or transmission FET. In addition, the calibration device can also be formed on the scribe line on the testing wafer. The calibration device can be easily to remove after the inspecting process is finished. The calibration device can also form on a dummy wafer to be calibrated. After the calibration process is finished, this dummy wafer with the calibration device can be removed. Thus, the electricity and the functional of the testing wafer would not be affected.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A calibration device applied for a test apparatus with at least a first probe and a second probe, the calibration device comprising:
a first testing region and a second testing region, the first testing region and the second testing region divide into n×n sensing units respectively, the first testing region for generating n×n average electricity corresponding to a contact degree of the first probe contacted with the calibration device, and the second testing region for generating another n×n average electricity corresponding to a contact degree of the second probe is contacted with the calibration device, and the pitch is a distance between the center of the first testing region to the center of the second testing region that is the same as that of the center of the first probe to the center of the second probe.

2. The calibration device according to claim 1, wherein the structure of the first testing region and the second testing region is a paralleled plate capacitor which is formed by a top metal layer, a dielectric layer and a bottom metal layer.

3. The calibration device according to claim 2, wherein the dielectric layer is inter-metal dielectric (IMD) layer or inter-layer dielectric (ILD) layer.

4. The calibration device according to claim 1, wherein the numerical n is an integer larger than 1.

5. The calibration device according to claim 1, wherein average electricity is average capacitance.

6. The calibration device according to claim 1, wherein the first testing region and the second testing region includes a first sub testing region and a second sub testing region, and an interconnect structure is electrically connected the first sub testing region with the second sub testing region.

7. A calibration device applied for a test apparatus with at least a first probe and a second probe, the calibration device comprising:
a first testing region and a second testing region, the first testing region and the second testing region divide into m×m sensing units respectively, the first testing region for generating m×m electricity corresponding to a contact degree of the first probe contacted with the calibration device, and the pitch is a distance between the center of the first testing region to the center of the second testing region that is the same as that of the center of the first probe to the center of the second probe.

8. The calibration device according to claim 7, wherein the structure of the first testing region and the second testing region is a paralleled plate capacitor which is formed by a top metal layer, a dielectric layer and a bottom metal layer.

9. The calibration device according to claim 7, wherein the dielectric layer is inter-metal dielectric (IMD) layer or inter-layer dielectric (ILD) layer.

10. The calibration device according to claim 9, wherein the numerical m is an integer larger than 1.

11. The calibration device according to claim 7, wherein the electricity is capacitance.

12. The calibration device according to claim 7, wherein the first testing region and the second testing region include a first sub testing region and a second sub testing region, and an interconnect structure is electrically connected the first sub testing region with the second sub testing region.

13. A calibration method applied for a test apparatus with at least a first probe and a second probe, the steps of the calibration method comprising:
providing a first testing region and a second testing region, the interval between the first testing region and the second testing region is same as the interval between the first probe and the second probe;
aligning the first probe and the second probe at the first testing region and the second testing region respectively;
receiving a first electricity and a second electricity from the first testing region and the second testing region, wherein the first electricity is obtained corresponding to a contact degree of the first probe contacted with the first testing region and the second electricity is obtained corresponding to a contacted degree of the second probe contacted with the second testing region respectively; and
calibrating the first probe and the second probe according to the first electricity and/or the second electricity.

14. The calibration method according to claim 13, wherein the first testing region and the second testing region is divided into at least n×n sensing units.

15. The calibration method according to claim 14, wherein the numerical n is an integer larger than 1.

16. The calibration method according to claim 13, wherein the first electricity and the second electricity is capacitance.

17. The calibration method according to claim 13, wherein further comprising calculating the first electricity and the second electricity to obtain average electricity, so that the average height for the first probe and the second probe can be obtained.

18. The calibration method according to claim 17, wherein the height difference is larger than a tolerance, the first probe or the second probe with corresponding height difference is to be replaced.

19. The calibration method according to claim 17, wherein when the average height is in the middle of the tolerance, the first probe and the second probe are adjusted to an inclined angle, and the first probe and the second probe have the same average height to be inspected.

20. The calibration method according to claim 17, wherein comprising calculating the first electricity or the second electricity to obtain the driving force in response to the first probe or the second probe.
